(19) United States
(12) Patent Application Publication
(10) Pub. No.: US 2008/0001097 A1
(43) Pub. Date: Jan. 3, 2008

(54) Electron beam drawing apparatus, electron beam drawing method, and a semiconductor device manufacturing method

(76) Inventors: Tetsuro Nakasugi, Yokohama-shi (JP); Takiji Ishimura, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/812,008

(22) Filed: Jun. 14, 2007

(30) Foreign Application Priority Data
Jun. 16, 2006 (JP) 2006-167632

(51) Int. Cl. G03F 7/23; H01L 21/66

(52) U.S. Cl. 250/398; 438/5; 257/E21.521

(57) ABSTRACT

An electron beam drawing apparatus includes an acquisition unit which acquires a position data of an Nth drawing area, an acquisition unit which acquires a stage position and speed, a prediction unit which predicts a stage position when drawing on the Nth area is carried out, a determination unit which determines whether a distance from the stage position to the Nth area position is less than a deflection distance, a decision unit which, when the distance is less than the deflection distance, corrects a deflection distortion in accordance with the determined distance and decides a deflection voltage, a detection unit which detects a drawing end of an (N-1)th drawing area when drawing on the (N-1)th area is ended, and a drawing unit which, when the drawing end is detected, deflects an electron beam in accordance with the deflection voltage to draw a pattern on the Nth area.

### CROSS-REFERENCE TO RELATED APPLICATIONS

This application is based upon and claims the benefit of priority from prior Japanese Patent Application No. 2006-167632, filed Jun. 16, 2006, the entire contents of which are incorporated herein by reference.

### BACKGROUND OF THE INVENTION

1. Field of the Invention

The present invention relates to an electron beam drawing apparatus, an electron beam drawing method, and a semiconductor device manufacturing method. In particular, the present invention relates to electron beam drawing apparatus and method that draw a circuit pattern of a semiconductor integrated circuit, and a semiconductor device manufacturing method.

2. Description of the Related Art

Recently, an electron beam drawing apparatus employs a continuous stage-moving type drawing method to improve throughput. According to the drawing method, a drawing control circuit sets an electron beam deflection distance to a desired drawing position data converted into a stage coordinate system, based on positional data obtained by a stage position measuring system. The electron beam deflection distance is a distance from a present stage position to the desired drawing position. With the continuous stage-moving type drawing method, the time required for moving the stage is reduced, in comparison with the step and repeat method. Therefore, patterns are drawn at high speed. However, in accordance with the recent tendency toward pattern miniaturization, the continuous stage-moving type drawing method has the following disadvantage.

FIG. 21 shows a conventional drawing flow in the continuous stage-moving type drawing method. According to the conventional drawing flow, the following steps S1 to S8 are executed. In step S1, previous sub-field end is confirmed. In step S2, a present stage position and sub-field data are acquired. In step S3, a distance from the present stage position to a target sub-field drawing position is calculated. In step S4, it is determined whether or not the distance from the present stage position to the target position is within a deflection distance (beam deflectable area). In step S5, if the distance from the present stage position to the target is within the deflection distance, a deflection distortion is calculated in accordance with the distance to determine a deflection voltage. In step S6, data is transferred to a deflection amplifier. In step S7, drawing is waited by a settling time to stabilize the voltage of the deflection amplifier. In step S8, drawing is carried out.

However, several tens of μsec are taken to perform steps S1 to S5. From step S1 to step S5, drawing is not actually carried out; for this reason, wasteful time is consumed. Recently, the miniaturization of pattern advances, and the number of patterns increases. As a result, the wasteful time becomes much; for this reason, throughput is reduced.

The following proposal has been made as a method of correcting an irradiation position of electron beam (e.g., see Japanese Patent No. 3394233). According to the proposal, irradiation positional shift on a substrate surface is previously measured with respect to each graphic aperture. Thereafter, the irradiation positional shift is fed back to an objective deflector. However, the foregoing correction method disclosed in Japanese Patent No. 3394233 has the following problem. Specifically, if the number of graphic apertures is great, much time is taken to measure the irradiation position with respect to each graphic aperture and to adjust a beam axis. In addition, a larger number of data including parameters for adjusting the beam axis are required.

### BRIEF SUMMARY OF THE INVENTION

According to an aspect of the present invention, there is provided an electron beam drawing apparatus of stage continuous-moving type comprising:

an acquisition unit which acquires a position data of an Nth drawing area;

an acquisition unit which acquires a stage position and a stage speed of a stage;

a prediction unit which predicts a stage position of the stage when drawing a pattern on the Nth drawing area is carried out;

a determination unit which determines whether or not a distance from the predicted stage position to the Nth drawing area position is less than a deflection distance;

a decision unit which, when the determination unit determines that the distance from the predicted stage position to the Nth drawing area position is less than the deflection distance, corrects a deflection distortion in accordance with the determined distance and decides a deflection voltage;

a detection unit which detects a drawing end of an (N-1)th drawing area when drawing a pattern on the (N-1)th drawing area is ended; and

a drawing unit which, when the drawing end of the (N-1)th drawing area is detected, deflects an electron beam in accordance with the deflection voltage decided by the decision unit to draw a pattern on the Nth drawing area.

According to another aspect of the present invention, there is provided an electron beam drawing method of stage continuous-moving type comprising:

acquiring a position data of an Nth drawing area;

acquiring a stage position and a stage speed of a stage;

predicting a stage position of the stage when drawing a pattern on the Nth drawing area is carried out;

determining whether or not a distance from the predicted stage position to the Nth drawing area position is less than a deflection distance;

correcting a deflection distortion in accordance with the determined distance and decides a deflection voltage, when the determination unit determines that the distance from the predicted stage position to the Nth drawing area position is less than the deflection distance;

detecting a drawing end of an (N-1)th drawing area when drawing a pattern on the (N-1)th drawing area is ended; and

deflecting an electron beam in accordance with the deflection voltage decided by the decision unit and drawing a pattern on the Nth drawing area, when the drawing end of the (N-1)th drawing area is detected.

According to a further aspect of the present invention, there is provided a semiconductor device manufacturing method comprising:

acquiring a position data of an Nth drawing area on an semiconductor wafer to be processed;

acquiring a stage position and a stage speed of a stage on which the semiconductor wafer is placed;

predicting a stage position of the stage when drawing a pattern on the Nth drawing area is carried out;

determining whether or not a distance from the predicted stage position to the Nth drawing area position is less than a deflection distance;

correcting a deflection distortion in accordance with the determined distance and decides a deflection voltage, when the determination unit determines that the distance from the predicted stage position to the Nth drawing area position is less than the deflection distance;

detecting a drawing end of an (N-1)th drawing area on the semiconductor wafer when drawing a pattern on the (N-1)th drawing area is ended; and

deflecting an electron beam in accordance with the deflection voltage decided by the decision unit to draw a pattern on the Nth drawing area of the semiconductor wafer, when the drawing end of the (N-1)th drawing area of the semiconductor wafer is detected.

### BRIEF DESCRIPTION OF THE SEVERAL VIEWS OF THE DRAWING

FIG. 1 is a block diagram schematically showing the configuration of an electron beam drawing apparatus according to a first embodiment of the present invention;

FIG. 2 is a view to explain a continuous stage-moving of an electron beam drawing method according to the first embodiment of the present invention;

FIG. 3 is a partial block diagram showing each configuration of a computer and a control circuit included in the electron beam drawing apparatus according to the first embodiment of the present invention;

FIG. 4A is a view showing a data format of drawing data relevant to the electron beam drawing apparatus and method according to the first embodiment of the present invention;

FIG. 4B is a view to explain the drawing data shown in FIG. 4A;

FIG. 4C is a view to explain the drawing data shown in FIG. 4A;

FIG. 5A is a view showing a chip layout relevant to the electron beam drawing apparatus and method according to the first embodiment of the present invention;

FIG. 5B is a table showing a chip position data relevant to the electron beam drawing apparatus and method according to the first embodiment of the present invention;

FIG. 6A is a view showing a chip data relevant to the electron beam drawing apparatus and method according to the first embodiment of the present invention;

FIG. 6B is a table showing a frame position data relevant to the electron beam drawing apparatus and method according to the first embodiment of the present invention;

FIG. 7A is a view showing a stripe layout relevant to the electron beam drawing apparatus and method according to the first embodiment of the present invention;

FIG. 7B is a table showing a stripe position data relevant to the electron beam drawing apparatus and method according to the first embodiment of the present invention;

FIG. 8 is a table to explain procedure data applied to the electron beam drawing apparatus and method according to the first embodiment of the present invention;

FIG. 9 is a block diagram showing the configuration of a development circuit applied to the electron beam drawing apparatus and method according to the first embodiment of the present invention;

FIG. 10 is a block diagram showing the configuration of a position correction circuit applied to the electron beam drawing apparatus and method according to the first embodiment of the present invention;

FIG. 11 is a view showing a transmission data from the data development circuit applied to the electron beam drawing apparatus and method according to the first embodiment of the present invention;

FIG. 12 is a flowchart to explain an electron beam drawing method of the electron beam drawing apparatus according to the first embodiment of the present invention, in particular, to explain a drawing flow of an operation section included in a deflection control circuit;

FIG. 13 is a block diagram showing the configuration of an operation section included in the deflection control circuit applied to the electron beam drawing apparatus and method according to the first embodiment of the present invention;

FIG. 14 is a timing chart of the electron beam drawing method according to the first embodiment of the present invention;

FIG. 15 is a flowchart to explain a drawing flow in an electron beam drawing method according to a second embodiment of the present invention;

FIG. 16 is a block diagram showing each configuration of a computer and a control circuit included in an electron beam drawing apparatus according to the second embodiment of the present invention;

FIG. 17A is a graph to explain the relationship between a drawing elapsed time and a stage position in the electron beam drawing apparatus and method according to the second embodiment of the present invention;

FIG. 17B is a graph to explain the relationship between a drawing elapsed time and a stage position in the electron beam drawing apparatus and method according to the second embodiment of the present invention;

FIG. 18 is a table showing predicted moving-stage data in the electron beam drawing apparatus and method according to the second embodiment of the present invention;

FIG. 19 is a flowchart to explain an electron beam drawing method of the electron beam drawing apparatus according to the second embodiment of the present invention, in particular, to explain a drawing flow of an operation section included in a deflection control circuit;

FIG. 20 is a block diagram showing the configuration of the operation section included in the deflection control circuit applied to the electron beam drawing apparatus and method according to the second embodiment of the present invention; and

FIG. 21 is a drawing procedure flow in a conventional electron beam drawing apparatus and method.

### DETAILED DESCRIPTION OF THE INVENTION

The first and second embodiments of the present invention will be hereinafter described with reference to the accompanying drawings. In the following drawings, the same or similar numbers are used to designate the same or similar portions.

### First Embodiment

(Configuration)

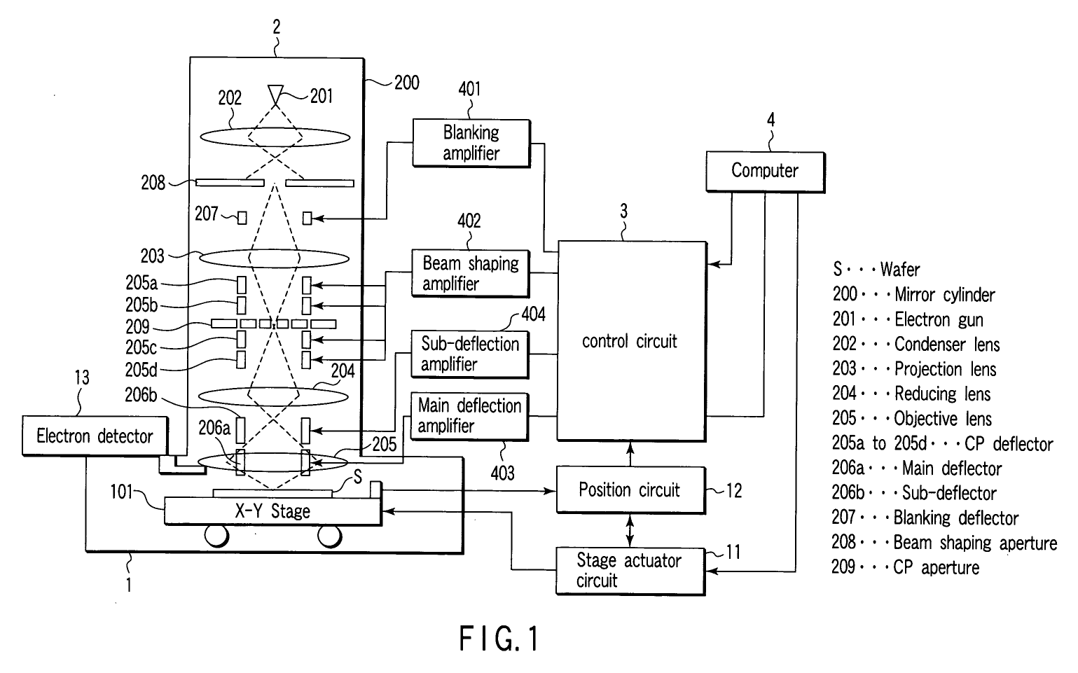

FIG. 1 is a block diagram showing the configuration of an electron beam drawing apparatus according to a first embodiment of the present invention. The electron beam drawing apparatus according to the first embodiment of the present invention employs a stage continuous-moving system and main and sub, that is, two-deflection system.

In a chamber 1, an X-Y stage 101 on which a wafer (sample, semiconductor substrate) S is placed is received. The X-Y stage 101 is actuated by a stage actuator circuit 11. A position of the X-Y moving stage 101 is measured by a position circuit 12 comprising a laser measuring unit. A secondary electron and a reflection electron from a wafer S are detected by an electron detector 13.

An electron optical system 2 is provided in a mirror cylinder above the chamber 1. The electron optical system 2 is composed of an electron gun 201, various lenses, various deflectors, a beam shaping aperture 208 and a CP aperture 209. The various lenses are a condenser lens 202, a projection lens 203, a reducing lens 204 and an objective lens 205. Moreover, the various deflectors are CP deflectors 205a to 205d, a main deflector 206a, a sub-deflector 206b, and a blanking deflector 207. In FIG. 1, there is no illustration of a beam control electrode and a coil included in a conventional electron beam drawing apparatus.

A control circuit 3 controls the blanking deflector 207 via a blanking amplifier 401. The blanking deflector 207 turns on and off the beam. Further, the control circuit 3 controls the CP deflectors 205a to 205d via the beam shaping amplifier 402. The CP deflectors 205a to 205d shape the beam. Furthermore, the control circuit 3 controls the main deflector 206a via a main deflection amplifier 403, and controls the sub-deflector 206b via a sub-deflection amplifier 404. In this way, the beam is scanned on the wafer S. In this case, an acceleration voltage is 5 keV, and the deflection areas of the main and sub-deflectors 206a and 206b are 1.5 mm and 50 μm, respectively.

According to main and sub, that is, two-deflection system, the main deflector 206a positions a sub-deflection area in a wide range such as several mm. Then, the sub-deflector 206b positions shots in a range such as several tens of μm at high speed. In this way, drawing on a drawing area is carried out at high speed. According to the two-deflection system, chip data (drawing data) is divided into a belt-like main deflection area, called a frame. A sub-deflection area position in the main deflection area is positioned using the main deflector 206a. A shot position in the sub-deflection area is positioned using the sub-deflector 206b.

(Continuous Stage-Moving System)

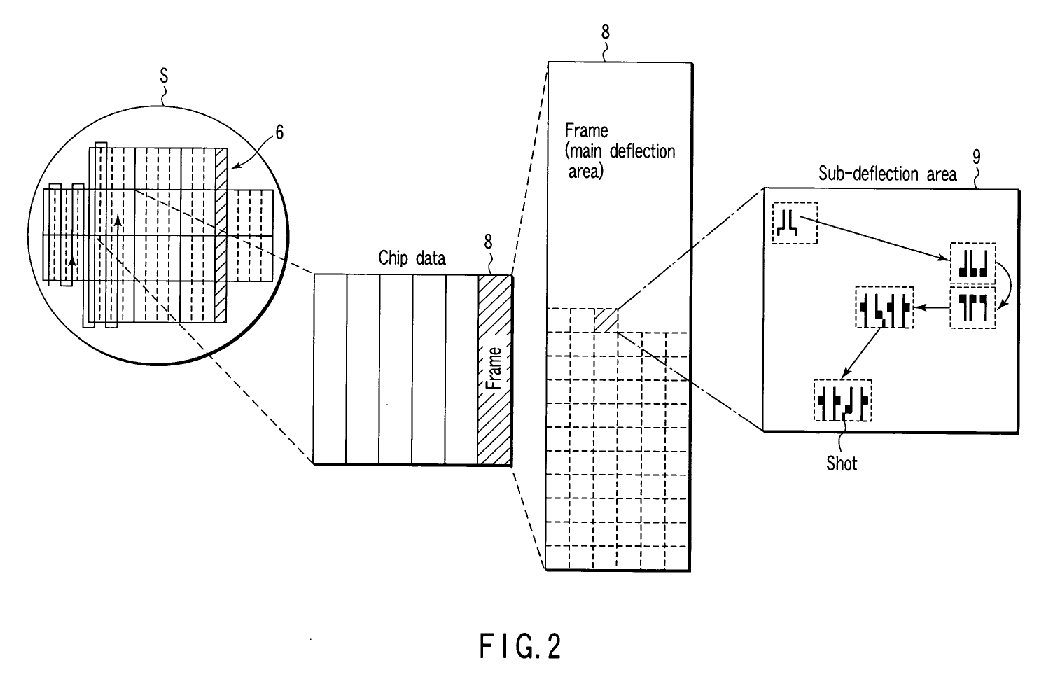

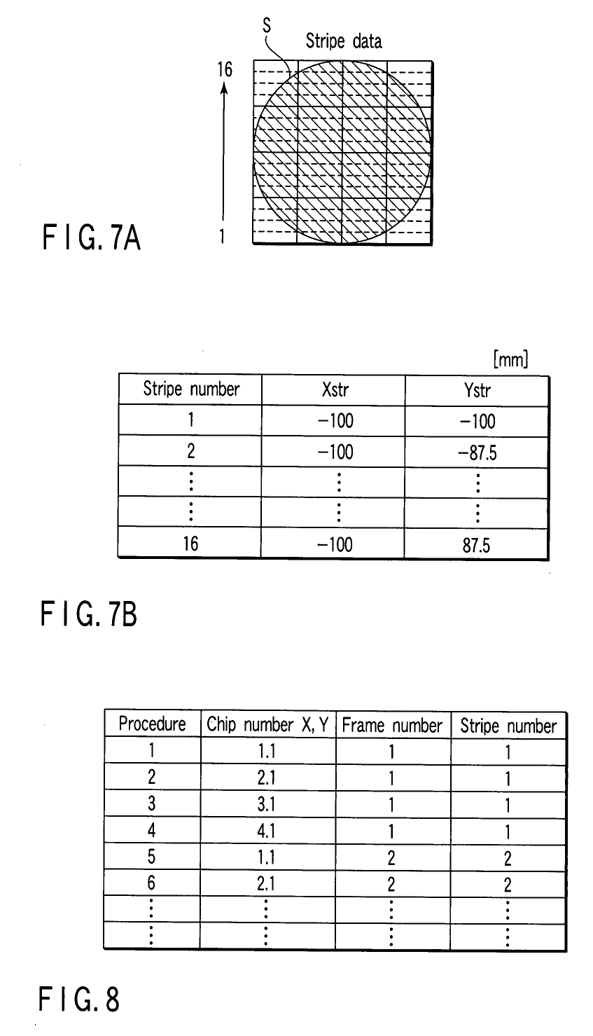

Continuous stage-moving of the electron beam drawing method according to the first embodiment of the present invention will be described with reference to FIG. 2. According to the continuous stage-moving, a plurality of chips on the wafer S is divided into a belt-like main deflection area, called a stripe, as shown in FIG. 2. Then, the X-Y stage 101 is continuously actuated to carry out drawing. According to the continuous stage-moving, the number of times of step moving of the X-Y stage 101 is reduced; therefore, high throughput is expected. In FIG. 2, the stripe is vertically divided; however, it may be horizontally divided. In, for example, FIG. 7, the stripe is horizontally divided.

A series of the foregoing control is executed according to a control program stored in a computer 4 shown in FIG. 1. The control program operates various units of the control circuit 3 according to electron beam (EB) drawing data and layout data, and thus, drawing is carried out.

(Electron Beam Drawing Apparatus)

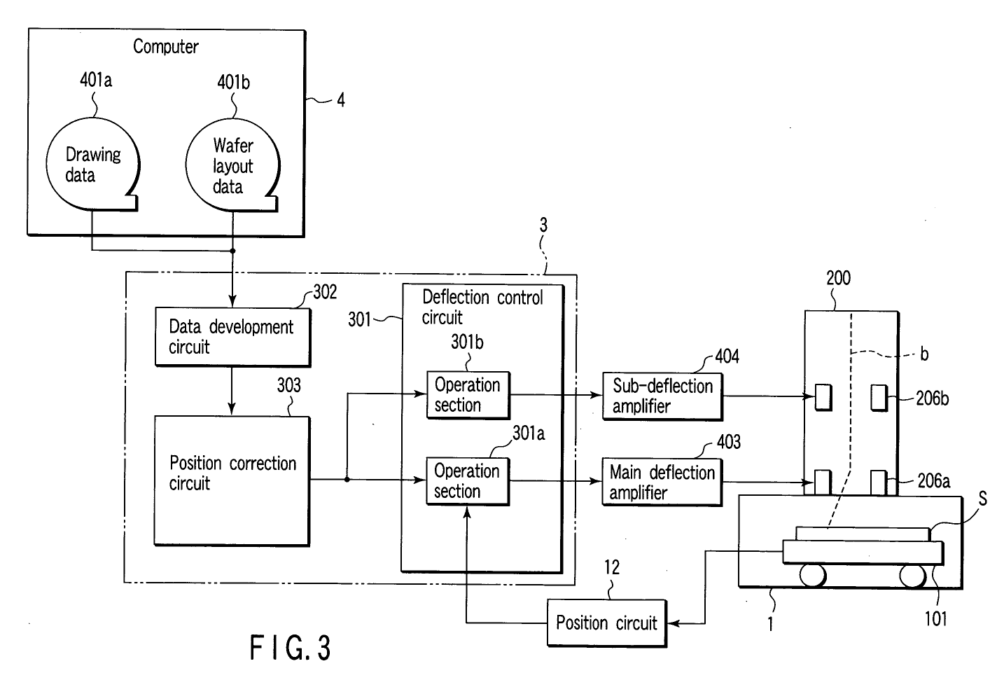

FIG. 3 is a schematic block diagram showing each configuration of a computer 4 and a control circuit 3 included in the electron beam drawing apparatus according to the first embodiment of the present invention. The function of each unit will be explained with reference to FIG. 3. In FIG. 3, the same reference numbers are used to designate portions the same as in FIG. 1. Incidentally, the procedure of transferring parameters to a deflection control circuit 301, that is, the procedure executed in the conventional electron beam drawing apparatus is omitted.

The computer 4 includes a storage for storing a drawing data 401a and a wafer layout data 401b (including procedure data, chip position data, frame position data, stripe position data). The control circuit 3 includes a deflection control circuit 301, a data development circuit 302 and a position correction circuit 303. The deflection control circuit 301 includes operation sections 301a and 301b. The drawing data 401a and the wafer layout data 401b are written into the data development circuit 302 from computer 4.

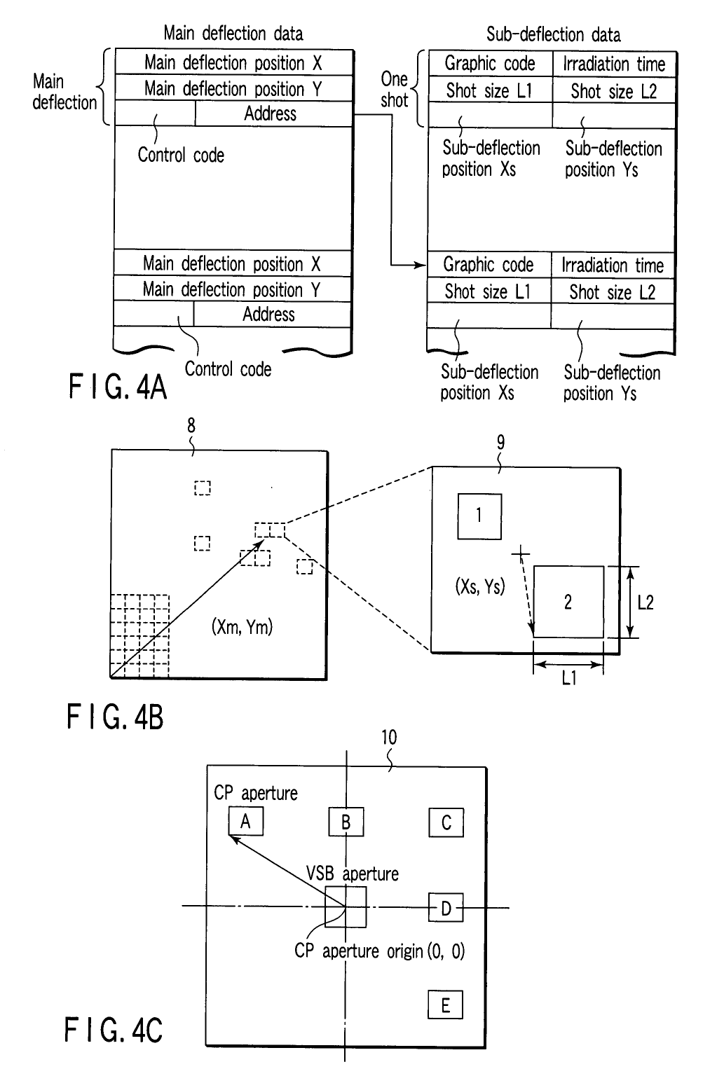

FIGS. 4A, 4B and 4C show views to explain the details of a drawing data structure relevant to electron beam drawing apparatus and method according to the first embodiment of the present invention. FIG. 4A is a view showing a data format of the drawing data 401a. FIG. 4B is a view to explain each data of FIG. 4A. As seen from FIG. 4A, the drawing data 401a is composed of a main deflection data for controlling the main deflector 206a and a sub-deflection data (shot data) for controlling the sub-deflector 206b.

The main deflection data describes a sub-deflection area position (Xm, Ym) in the main deflection area, an address showing data start position of shots included in the sub-deflection area, and a control code including the number of shots in the sub-deflection area. The sub-deflection area position (Xm, Ym) in the main deflection area is described as the center position of the sub-deflection area when the origin of the frame is set as the reference. Namely, the sub-deflection area position (Xm, Ym) shows a drawing position of the sub-deflection area in the frame coordinate system.

The sub-deflection data describes a position (Xs, Ys) in the sub-deflection area of each of the shots, a graphic code for controlling the CP deflectors 205a to 205d, irradiation time, and shot size. In this case, the shot position (Xs, Ys) is described as a shot lower left position when the center position of the sub-deflection area is set as the origin. The graphic code expresses the position of each of CP apertures (A to E) on the CP aperture from the CP aperture origin (0, 0). The shot size describes a width and a height when the shot lower left corner point is set as the origin.

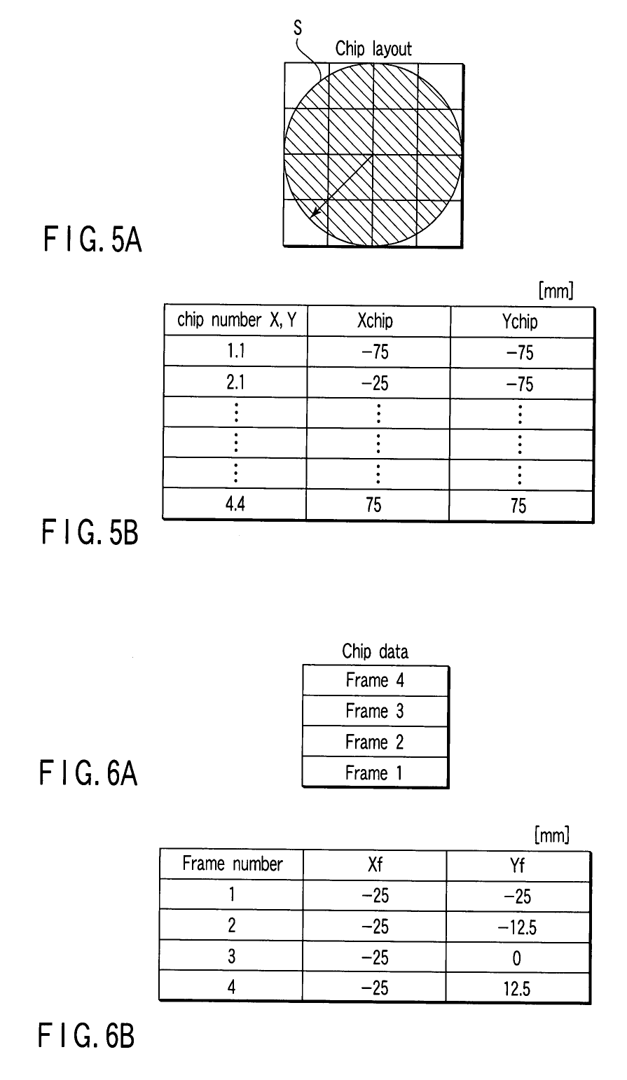

FIGS. 5A and 5B, FIGS. 6A and 6B, FIGS. 7A and 7B, and FIG. 8 show views to explain the details of the wafer layout data 401b in the electron beam drawing apparatus and method according to the first embodiment of the present invention. The wafer layout data 401b includes chip position data, frame position data, stripe position data and procedure data. In the electron beam drawing apparatus of this embodiment, the deflection areas of main and sub-deflectors 206a and 206b have a size of 1.5 mm and a size of 50 μm, respectively. In FIG. 5A to FIG. 8, in order to simplify the explanation, the wafer has a diameter of 200 mm, the chip is 25 mm square, and the frame width is 6.25 mm.

FIG. 5A is a view showing the chip layout. FIG. 5B is a table showing the chip position data. As shown in FIG. 5B, according to the chip position data, a chip number (X, Y) is given to each chip arrayed on the wafer S of FIG. 5A. In this way, each chip position Xchip, Ychip on the wafer coordinate system is described, using the center of the wafer as the origin.

FIGS. 6A and 6B show the details of chip data in the electron beam drawing apparatus and method according to the first embodiment of the present invention. FIG. 6A is a view showing the chip data. FIG. 6B is a table showing a frame position data generated from the chip data. As shown in FIG. 6B, according to the frame position data, a frame origin position Xf, Yf corresponding to the frame number on the chip coordinate system using the chip center as the origin is described with respect to each of the frames of the chip data shown in FIG. 6A.

FIGS. 7A and 7B show the details of stripe data in electron beam drawing apparatus and method according to the first embodiment of the present invention. FIG. 7A is a view showing a stripe layout. FIG. 7B is a table showing stripe position data generated from the chip layout data and the frame position data. As depicted in FIG. 7A, a drawing area on the wafer S is divided into stripes. According to the stripe position data, a stripe origin position Xstr, Ystr corresponding to each stripe number is described as shown in FIG. 7B. In this case, the origin position of each frame shown in FIG. 6B is added to each chip origin position shown in FIG. 7B, so that the stripe origin position Xstr, Ystr shown in FIG. 7B is obtained.

FIG. 8 shows the details of procedure data applied to the electron beam drawing apparatus and method according to the first embodiment of the present invention. As shown in FIG. 8, according to the procedure data, the chip number, frame number and stripe number are described.

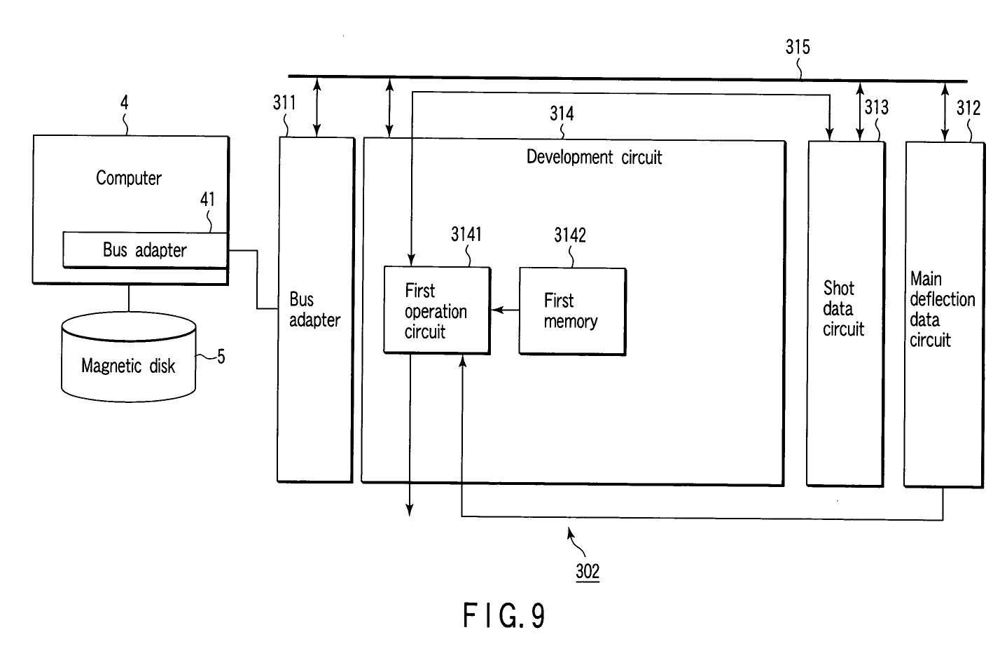

FIG. 9 is a block diagram showing the configuration of the data development circuit 302 applied to the electron beam drawing apparatus and method according to the first embodiment of the present invention.

The data development circuit 302 is composed of a bus adapter 311, a main deflection circuit 312, a shot data circuit 313 and a development circuit 314. These circuits are connected with a data bus 315. The chip data is written in the data development circuit 302 from the computer 4 via a bus adapter 41. The main deflection data is stored in the memory of the main deflection data circuit 312. The shot data is stored in the memory of the shot data circuit 313. The procedure data shown in FIG. 8 is stored in a first memory 3142 connected to a first operation circuit 3141 of the development circuit 314.

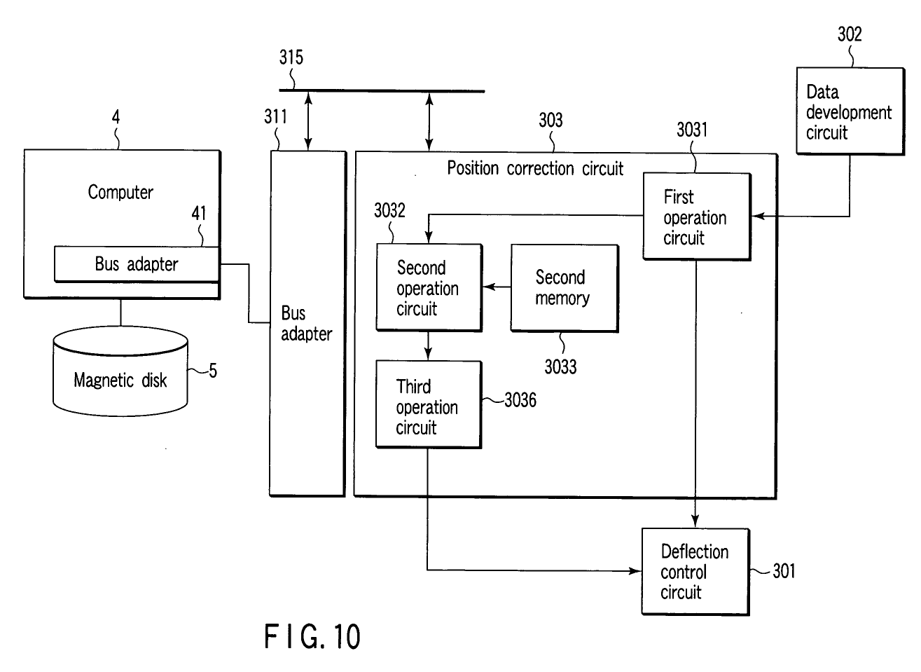

FIG. 10 is a block diagram showing the configuration of a position correction circuit 303 applied to electron beam drawing apparatus and method according to the first embodiment of the present invention.

The drawing data 401a is written in the data development circuit 302 from the computer 4. Further, the wafer layout data 401b (including chip position data, frame position data and stripe position data) is written in the position correction circuit 303 from the computer 4.

The chip position data shown in FIG. 5B, the frame position data shown in FIG. 6B and the stripe position data shown in FIG. 7B are stored in a second memory 3033 connected to a second operation circuit 3032 in the position correction circuit 303.

In FIG. 3, the wafer S is placed on the X-Y stage 101, and then, when drawing is ready for execution, the computer 4 instructs the data development circuit 302 to send data.

That the drawing is ready for execution means a state in which the start point for moving and the end point of the X-Y stage 101 are obtained, and the X-Y stage 101 is positioned at the start point.

The start point and the end point of the x-Y stage 101 are determined from a drawing start point and a drawing end point (Xstart, Xend) of each stripe. A run-up distance and a deceleration distance (X run-up distance, X deceleration distance) are determined with respect to drawing start and end points (Xstart, Xend) of each stripe in accordance with a stage speed of each stripe. Namely, the stage-moving start point and end point (Xstgs, Xstge) are determined in the following manner.

Case where the X-Y state is moved to the forward direction
Stage-moving start point(Xstgs)=drawing start point(Xstart)−run-up distance(X run-up distance)
Stage-moving end point(Xstge)=drawing end point(Xend)+deceleration distance(X deceleration distance)

Case where the X-Y state is moved to the backward direction
Stage-moving start point(Xstgs)=drawing start point(Xstart)+run-up distance(X run-up distance)
Stage-moving end point(Xstge)=drawing end point(Xend)−deceleration distance(X deceleration distance)

Specifically, transfer start address, the number of words and the number of transfer repeats are inputted to the main deflection data circuit 312 shown in FIG. 9. Thereby, the deflection data is transferred from the memory of the main deflection data circuit 312 to the first operation circuit 3141 of the development circuit 314. The main deflection data circuit 312 detects a half full (HF) flag of FIFO (First-in first-out) of the development circuit 314 to determine data send/temporary stop.

When data send instruction to the data development circuit 302 is executed, an instruction is issued from the computer 4 to the X-Y stage 101 (FIG. 1) to move. The stage 101 is moved by the stage actuator circuit 11 (FIG. 1) under the control of computer 4. The computer 4 specifies the end position and the speed of the stage.

The first operation circuit 3141 of the development circuit 314 receives the main deflection data from the main deflection data circuit 312 via FIFO, and when one main deflection data is read from the FIFO, shot data is read from the shot data circuit 313. Specifically, the start address of the shot data and the number of shots included in the main deflection data shown in FIG. 4A are designated to start the shot data circuit 313. The shot data circuit 313 sends shot data described in the address designated from the first operation circuit 3141 by the designated number of shots.

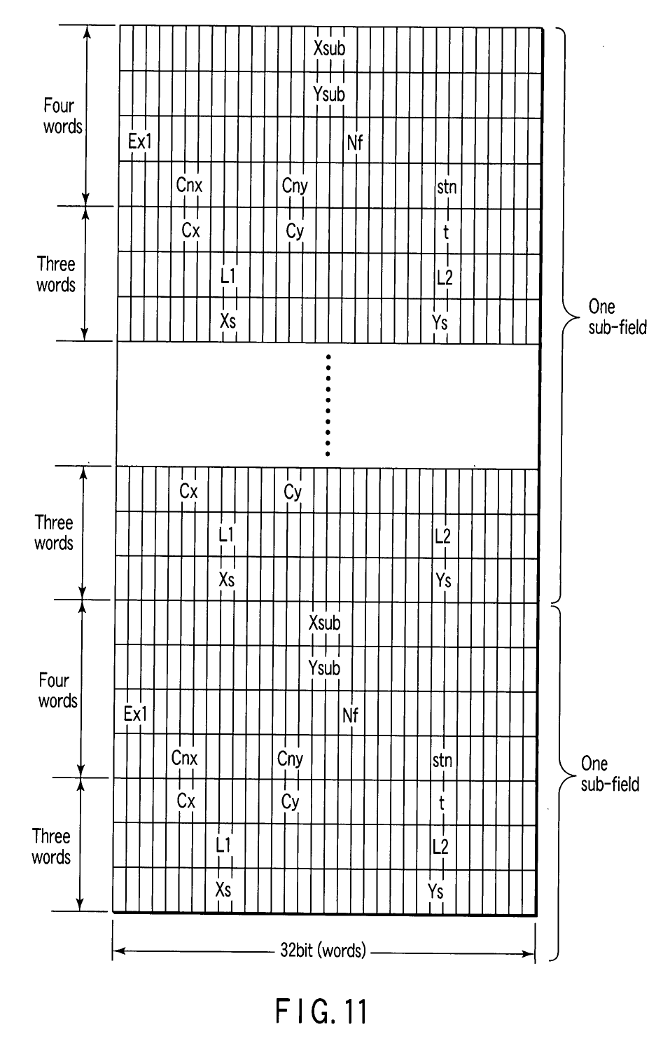

FIG. 11 shows data sent from the data development circuit applied to the electron beam drawing apparatus and method according to the first embodiment of the present invention.

In the first operation circuit 3141, data sent from the shot data circuit 313 is added to the main deflection data, as shown in the format of FIG. 11, and is sent to the after-stage position correction circuit 303. In this case, according to the procedure data stored in the first memory 3142, the chip number, the frame number and the stripe number are added to the main deflection data sent from the main deflection data circuit 313. A control code showing a frame end is added to the last sub-deflection position data of the frame. The operation circuit 3141 detects the control code to execute the next procedure of the procedure data.

The position correction circuit 303 divides the sent data into main deflection data and shot data. First, the first operation circuit 3031 divides the sent data into main deflection data and shot data. The main deflection data is sent to the second operation circuit 3032, while the shot data is sent to the operation section 301b of the deflection control circuit 301.

The second operation circuit 3032 of the position correction circuit 303 transforms the main deflection data including the chip number and the frame number sent from the data development circuit 302 into the wafer coordinate system.

The second operation circuit 3032 calls a chip position data stored in the second memory 3033 based on the chip number and reads the chip position Xchip, Ychip described on the wafer coordinate system using the wafer center as the origin.

The second operation circuit 3032 calls a frame position data stored in the second memory 3033 based on the frame number and reads the frame origin position Xf, Yf described on the chip coordinate system using the chip center as the origin.

The second operation circuit 3032 adds the chip position Xchip, Ychip, frame position Xf, Yf and main deflection position Xm, Ym. In this way, the circuit 3032 determines main deflection position Xmwf, Ymwf on the wafer coordinate system.
Xmwf=Xm+Xf+Xchip
Ymwf=Ym+Yf+Ychip

where, the main deflection position (Xmwf, Ymwf) shows a drawing position of the sub-deflection area (from th wafer origin) on the wafer coordinate system.

The third operation circuit 3036 carries out a correction for a positional error due to wafer distortion and chip distortion with respect to the main deflection data to improve the accuracy of the main deflection position (Xmwf, Ymwf). Further, the stage coordinate system using the wafer origin as a reference is added to the corrected main deflection position (Xmwf, Ymwf). In this way, the main deflection position is transformed from the wafer coordinate system into the stage coordinate system (Xmstg, Ymstg), and sent to the after-stage deflection control circuit 301. Incidentally, the third operation circuit 3036 is equipped with a memory, not shown, which stores a correction coefficient and a coordinate value required for the positional correction.

The deflection control circuit 301 shown in FIG. 3 handles the sent main deflection data and shot data. The operation section 301a calculates a main deflection position (Xmdef, Ymdef) using the following equation. In this case, the main deflection position (Xmdef, Ymdef) is calculated from the current stage coordinate (Xstg, Ystg) with respect to the main deflection data (Xmstg, Ymstg) transformed into the stage coordinate system.
Xmdef=Xmstg−Xstg
Ymdef=Ymstg−Ystg

The third operation circuit 3036 carries out a correction for a positional error due to wafer distortion and chip distortion with respect to the main deflection data to improve the accuracy of the main deflection position (Xmwf, Ymwf).

Further, the operation section 301a carries out a correction for a positional error due to lens distortion with respect to the main deflection data to improve the accuracy of the main deflection position (xmdef, Ymdef). In this case, the main deflection position (xmdef, Ymdef) means a drawing position of the sub-deflection area when the main deflection origin is set as a reference on the main deflection coordinate system. The main deflection position includes chip distortion corrections and wafer distortion corrections. The main deflection data (Xmstg, Ymstg) and the main deflection position (Xmdef, Ymdef) are sent to the main deflection amplifier 403 to generate a desired voltage of the main deflector 206a.

(Electron Beam Drawing Method)

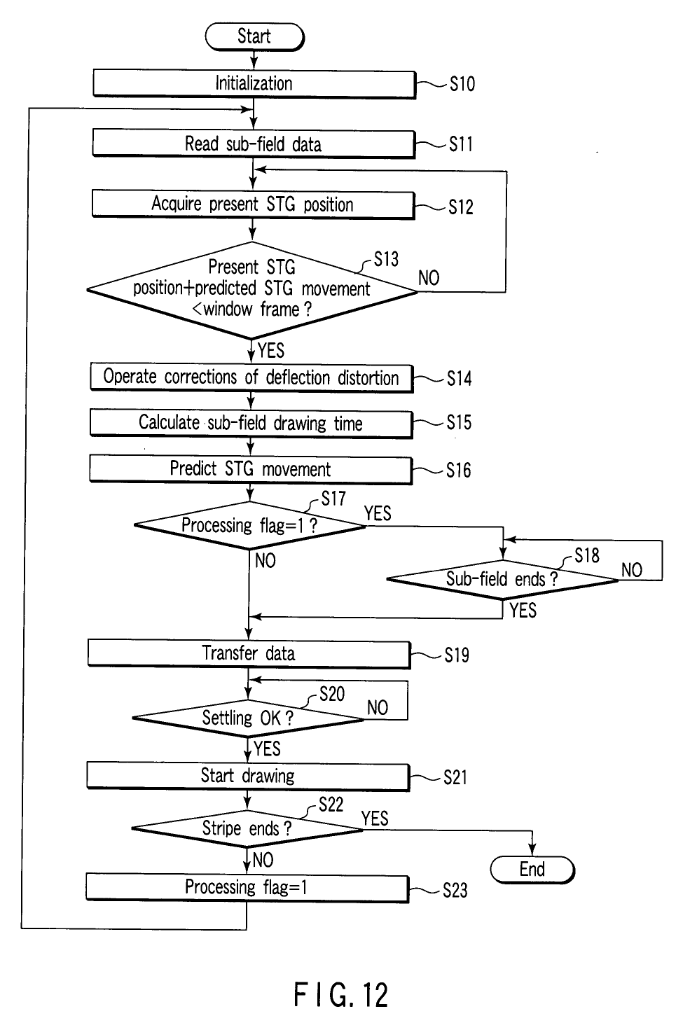

FIG. 12 is a flowchart to explain the electron beam drawing method of the electron beam drawing apparatus according to the first embodiment of the present invention. The flowchart is used to explain the drawing flow by the operation section 301a included in the deflection control circuit 301.

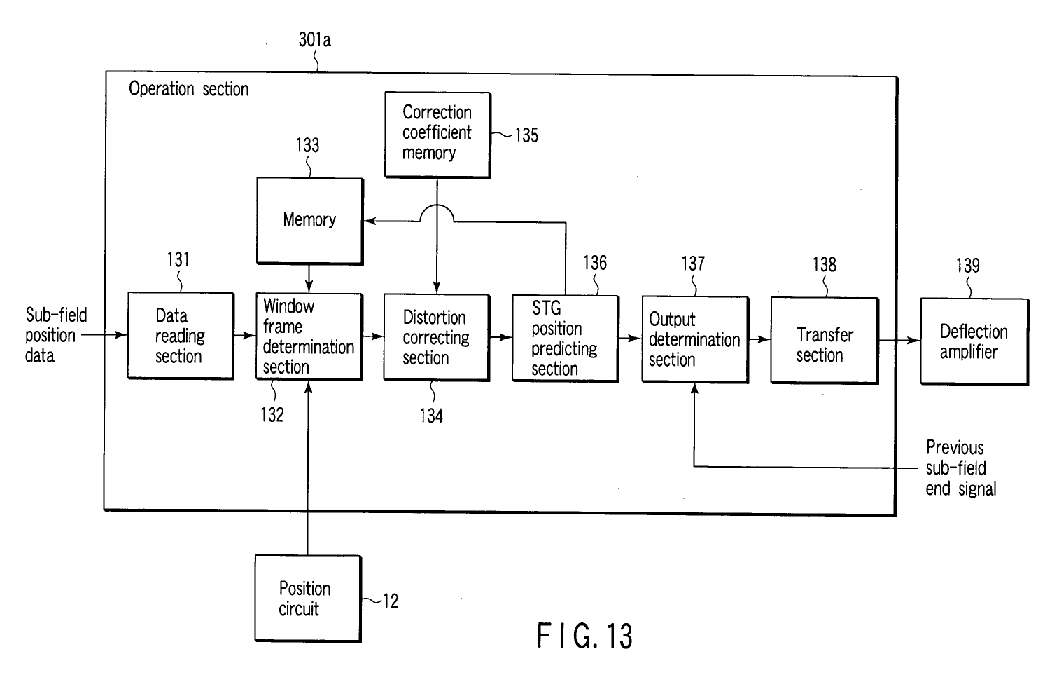

FIG. 13 is a block diagram showing the configuration of the operation section 301a of the deflection control circuit 301 used in the electron beam drawing apparatus and method according to the first embodiment of the present invention. According to the electron beam drawing method of the electron beam drawing apparatus according to the first embodiment, processing in the operation section 301a of the deflection control circuit 301 is effectively executed so that the processing speed is enhanced.

(a) In step S10, initialization is executed. In the initialization, a drawing process flag written in a memory of FIG. 13 is set to zero. The drawing process flag shows whether or not the first sub-field is given and whether or not a predicted stage position is used. Further, a predicted stage movement (predicted STG) stored in the memory 133 is set to zero.

(b) In step S11, a data reading section 131 in FIG. 13 reads a sub-field position data.

(c) In step S12, a window frame determination section 132 acquires the present stage position and a stage speed from the position circuit 12.

(d) In step S13, the window frame determination section 132 determines whether or not the stage position at the time of the sub-field drawing is within a deflection distance range based on the predicted stage movement read from the memory 133 and the present stage position. If it is determined that the stage position is within the deflection distance range, the flow proceeds to step S14. Conversely, if it is determined that the stage position is out of the deflection distance range, the flow returns to step S12. In step S13, the window frame determination section 132 again determines whether or not the stage position at the time of the sub-field drawing is within the deflection distance range. The foregoing operation is repeated until it is determined that the stage position at the time of the sub-field drawing is within a deflection distance range. The drawing process flag written in the memory 133 is read, and then, stored in a register (not shown).

(e) In step S14, a distortion correcting section 134 calculates a distance from the present stage position to a targeted sub-field drawing position. Then, the distortion correction section 134 reads a correction coefficient corresponding to the deflection distance from a correction coefficient memory 135 to calculate deflection distortion. Thereafter, the distortion correcting section 134 determines a deflection voltage.

(f) In step S15, a STG position predicting section 136 predicts sub-field drawing time based on the number of shots in sub-field included in the sub-field position data (drawing data) and average shot time.

(g) In step S16, the STG position predicting section 136 predicts a stage position after drawing is carried out on the sub-field drawing currently being in computation based on the sub-field drawing time and a stage speed read from the position circuit 12. Specifically, drawing time spent for sub-field drawing is multiplied by the stage speed so that a predicted stage movement during sub-field drawing is calculated. The predicted stage movement is written in the memory 133, and further, used when the next sub-field calculation is executed.

A flag for using the predicted stage movement at the next sub-field calculation is set to 1 and written in the memory 133. In order to calculate the predicted stage movement, the total time of data read time, window frame determination time and operating time is compared with the predicted sub-field drawing time. The total time or the predicted sub-field drawing time, whichever is larger, is multiplied by the stage speed to calculate the predicted stage movement. In this way, a high-accuracy predicted stage movement amount is obtained even if the number of shots in the sub-field is less and the drawing time is extremely short.

(h) The process flow proceeds to the step S19 if the drawing flag stored in step S13 in the register, not shown, is zero in step S17 in an output determination section 137.

(i) Conversely, if the drawing flag is 1 in step S17, the process flow proceeds to step S18. The output determination section 137 waits until a previous sub-field drawing end signal is detected. When the previous sub-field end signal is detected, the flow proceeds to the step S19.

(j) In step S19, the transfer section 138 transfers the data to the deflection amplifier 139.

(k) In step S20, the transfer section 138 waits until the predetermined settling time elapses.

(l) In step S21, when the voltage of the deflection amplifier 139 is stable, a drawing start (beam irradiation) signal is sent to the deflection amplifier 139.

(m) In step S22, if the data reading section 131 does not detect a stripe end flag showing the last sub-field in the stripe, the flow proceeds to step S23, and then, the drawing flag is set to 1, and the flow returns to step S11.

(n) Conversely, in step S22, if the data reading section 131 detects a stripe end flag showing the last sub-field in the stripe, the sub-field drawing end signal is detected, and then, the stripe drawing ends.

(Timing Chart)

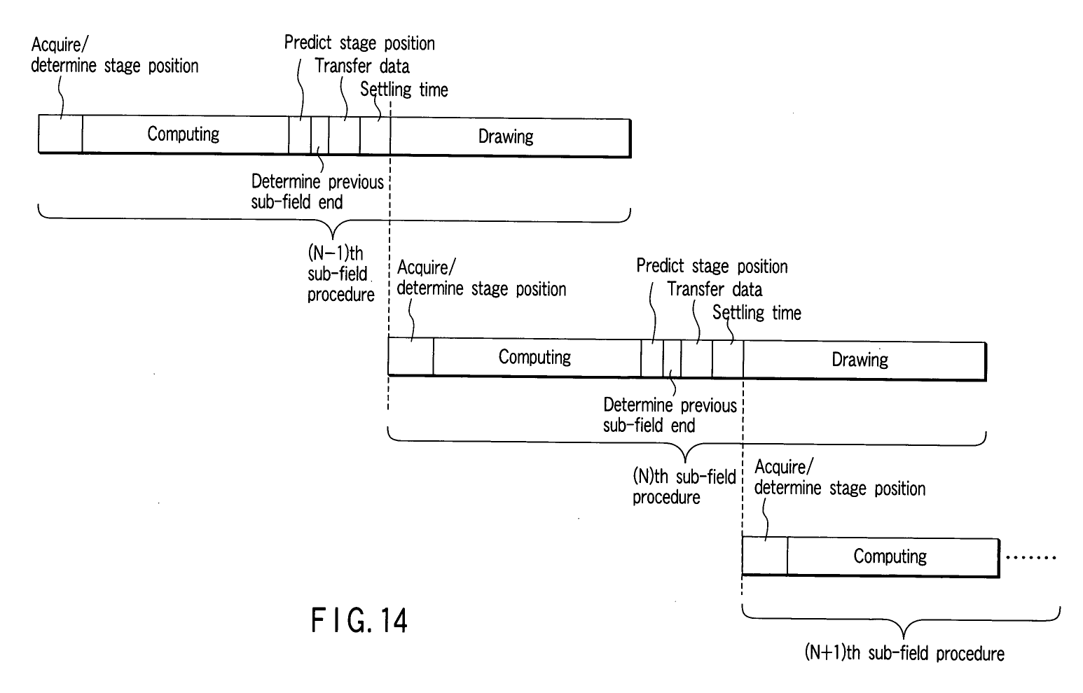

FIG. 14 is a timing chart showing the electron beam drawing method according to the first embodiment of the present invention.

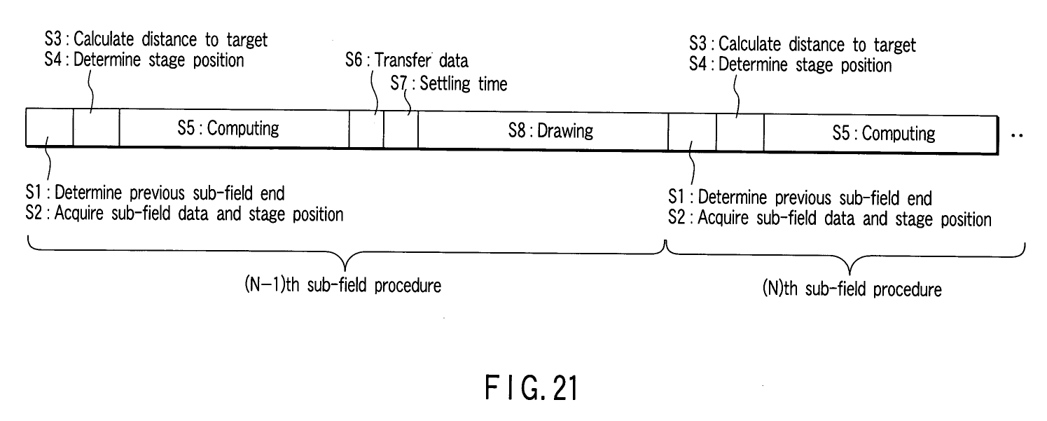

As shown in FIG. 14, the electron beam drawing method according to the first embodiment of the present invention starts deflection distortion computing to the next sub-field in the following manner. Specifically, when drawing is started, deflection distortion computing to the next sub-field is started based on the predicted stage position predicted during the previous sub-field computing (steps S15 and S16 in FIG. 12). As a result, wasteful time is largely reduced, and productivity by electron beam drawing is greatly improved compared with the prior art shown in FIG. 21.

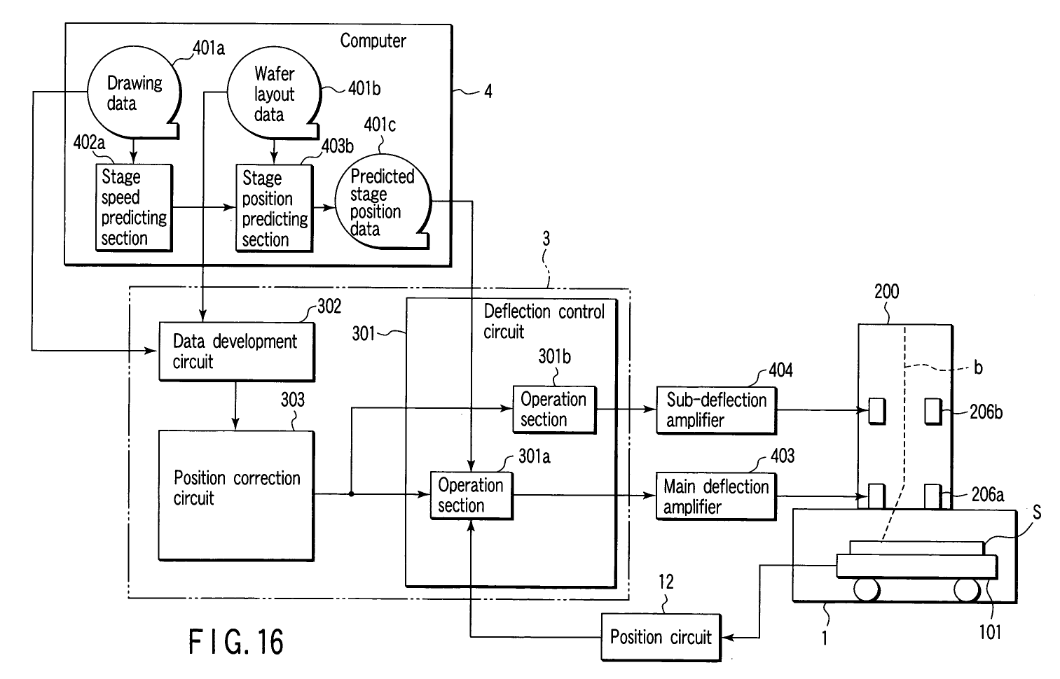

According to the electron beam drawing method according to the first embodiment of the present invention, procedures of deflection distortion correction, sub-field drawing time prediction and predicted stage movement amount are executed in the order in steps S14 to S16 of FIG. 16. The foregoing procedures may be executed in an order other than above. For example, procedures of sub-field drawing time prediction and stage movement amount prediction are executed, and thereafter, corrections of deflection distortion may be made.

In the electron beam drawing apparatus according to the first embodiment of the present invention, the operation section 301a of the deflection control circuit 301 shown in FIG. 13 is configured using a digital signal processor (DSP). In other words, a program for realizing the procedure flow shown in FIG. 12 is prepared, and then, the DSP executes the program. Preferably, an internal memory of the DSP is used as the memory 133 and the correction coefficient memory 135; in this case, an external memory may be used.

According to electron beam drawing apparatus and method according to the first embodiment of the present invention, the deflection control circuit predicts the stage position of the sub-field position to be drawing processed. In this way, deflection distortion is computed without waiting for the previous sub-field drawing to end. Therefore, wasteful time is largely reduced, and productivity by electron beam drawing is greatly improved.

### Second Embodiment

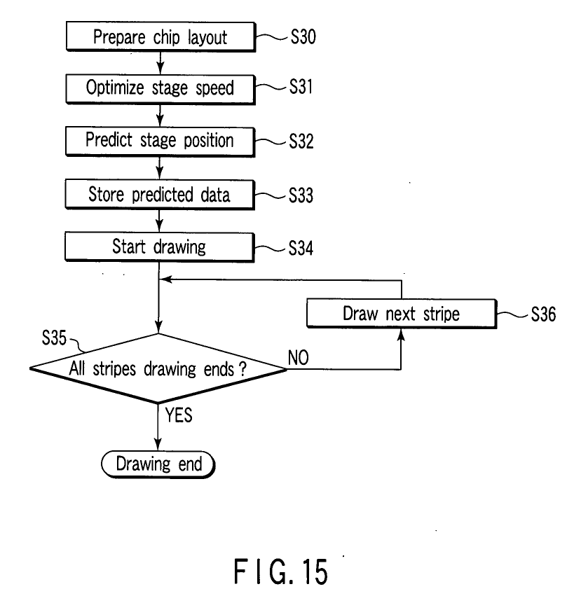

An electron beam drawing method according to a second embodiment of the present invention will be hereinafter described with reference to a flowchart shown in FIG. 15 to explain a drawing flow. FIG. 16 is a block diagram showing each configuration of a computer 4 and a control circuit included in an electron beam drawing apparatus according to a second embodiment of the present invention. According to the electron beam drawing method of the second embodiment, a stage position in drawing is beforehand predicted. Based on the predicted stage position, drawing is carried out.

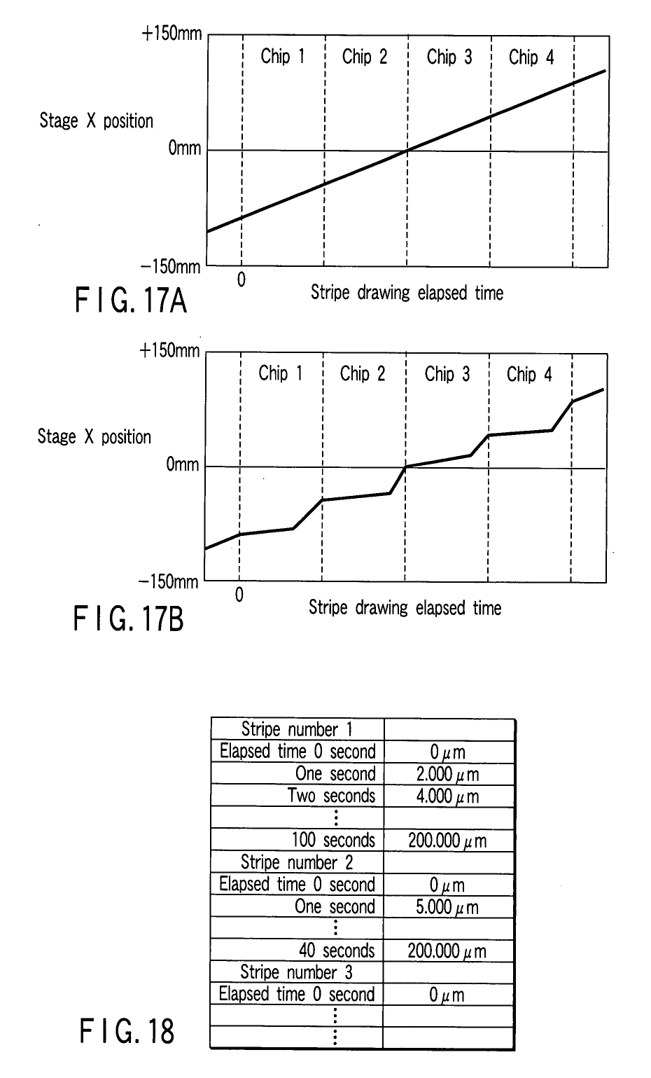

FIGS. 17A and 17B are graphs showing the relationship between drawing elapsed time and the stage position in the electron beam drawing apparatus according to the second embodiment of the present invention. FIG. 18 is a table showing predicted stage movement data in the electron beam drawing apparatus according to the second embodiment.

FIG. 17A shows the relationship between an elapsed time from strip drawing start and a stage position in a stripe when the stage speed is fixed. FIG. 17B shows the relationship between an elapsed time from strip drawing start and a stage position in a stripe when the stage speed changes according to coarse and density of a pattern in a chip. In FIG. 17B, the stage moves at a low speed in a place where the pattern is dense while it moves at a high speed in a place where it is coarse. Thus, the gradient of the stage position to the drawing elapsed time does not become constant. In this case, the stage movement amount is predicted with intervals of one second from the stripe drawing start, and then, a stage predicted movement data table shown in FIG. 18 is prepared.

(Variable Speed Adapted Drawing Method)

(a) In step S30 of FIG. 15, a chip layout (FIG. 5) on a wafer S is prepared, and then, the prepared wafer layout data 401b is stored in the computer 4.

(b) In step S31, a stage speed predicting section 402a calculates a stage speed every frame (stripe) with respect to the drawing data 401 stored in the computer 4.

(c) In step S32, a stage position predicting section 403b prepares a predicted stage position data 401c with respect to the elapsed time from the drawing start every stripe. The data 401c is prepared based on stage speed information every frame (stripe) calculated in step S32 and the wafer layout data 401b.

(d) In step S33, the predicted stage position data 401c is stored in the operation section 301a of the deflection control circuit 301.

(e) In step S34, the predicted stage position data 401c corresponding to the stripe is read based on stripe information described in the drawing data 401a in drawing. In the operation section 301a of the deflection control circuit 301, an internal timer measures an elapsed time from start of the stripe drawing. A predicted stage position in an elapsed time is calculated from the predicted stage movement, and thereafter, the same drawing as the first embodiment is carried out.

(f) In step S35, if there exists a stripe to be processed, the flow proceeds to step S36. If all stripes are fully processed, the drawing ends.

(g) In step S36, when the next stripe is processed, the predicted stage movement amount data corresponding to the stripe is read based on the stripe information described in the drawing data like the step S34. In the operation section 301a of the deflection control circuit 301, an internal timer measures an elapsed time from the start of the stripe drawing. A predicted stage position in an elapsed time is calculated from the predicted stage movement amount data, and thereafter, the same drawing as the first embodiment is carried out.

(h) When all stripes are processed, the drawing procedure ends.

(Electron Beam Drawing Method)

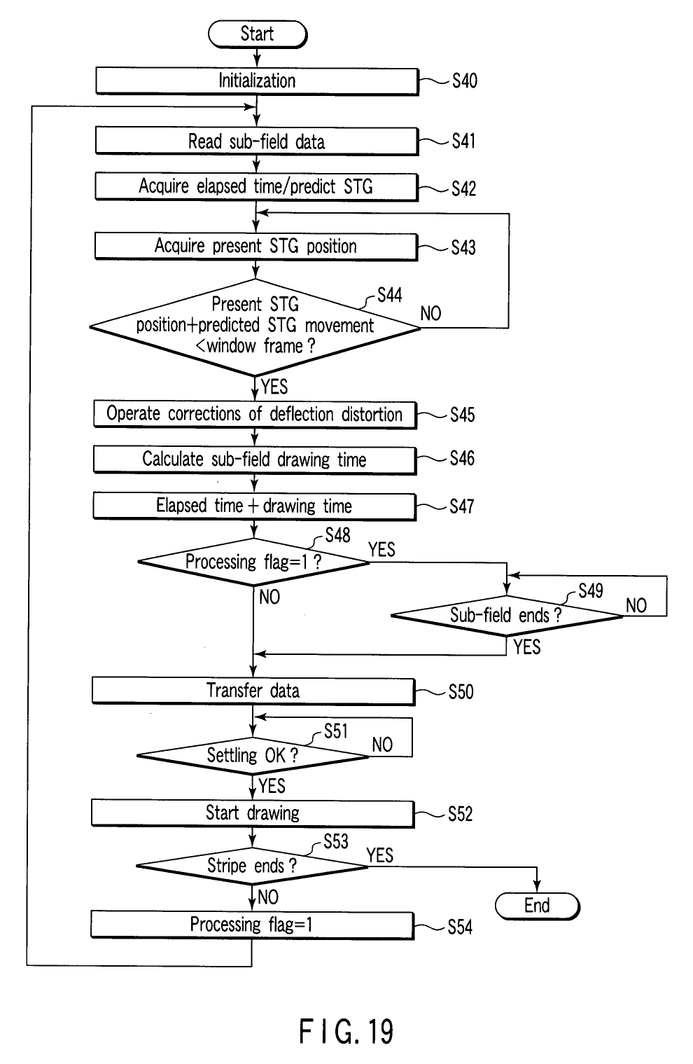

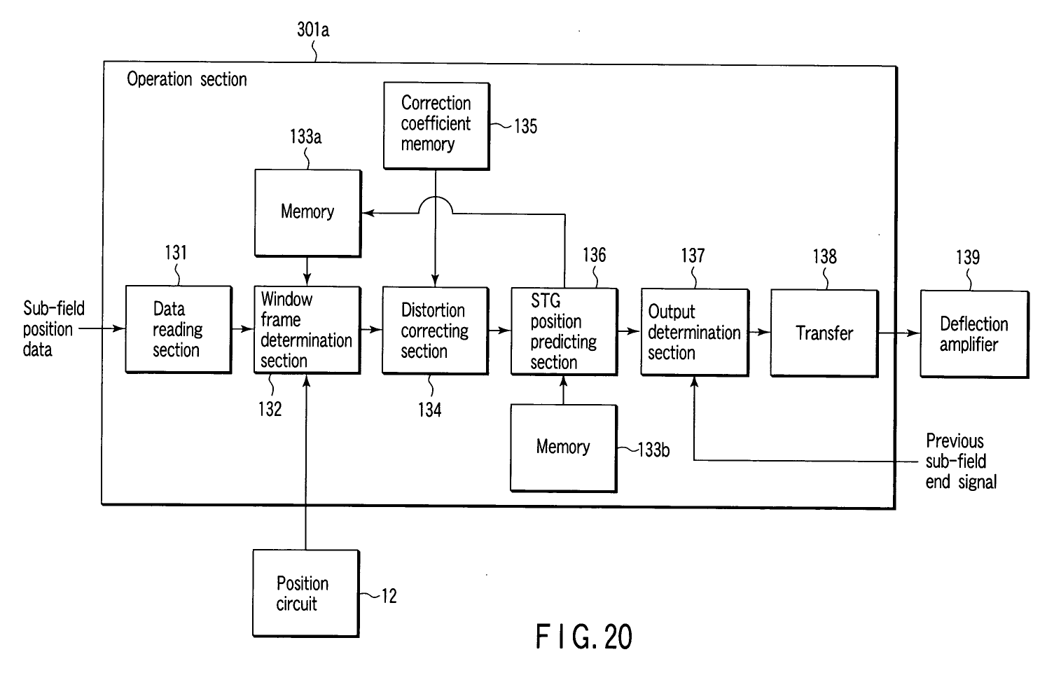

FIG. 19 is a flowchart to explain the electron beam drawing method of the electron beam drawing apparatus according to the second embodiment of the present invention, in particular, to explain the drawing flow of the operation section 301a of the deflection control circuit 301. FIG. 20 is a block diagram showing the configuration of the operation section 301a of the deflection control circuit 301 applied to the electron beam drawing method of the electron beam drawing apparatus according to the second embodiment of the present invention

(a) In step S40 of FIG. 19, initialization is executed. In the initialization, a drawing flag written in a memory 1331 of FIG. 20 is set to zero. The drawing flag shows whether or not the first sub-field is given and whether or not a predicted stage position is used. Further, a predicted stage movement amount (predicted STG) stored in the memory 133a is set to zero. An elapsed time timer starts to count

(b) In step S41, a data reading section 131 of FIG. 20 reads a sub-field position data.

(c) In step S42, a predicted stage movement amount is determined from the predicted stage movement amount stored in the memory 133a based on the elapsed time.

(d) In step S43, a window frame determination section 132 acquires the present stage position and a stage speed from the position circuit 12.

(e) In step S44, the window frame determination section 132 determines whether or not the stage position at the time of the sub-field drawing is within a deflection distance range based on the predicted stage movement amount read from the memory 133a and the present stage position. If it is determined that the stage position at the time of the sub-field drawing is within the deflection distance range, the flow proceeds to step S45. Conversely, if it is determined that the stage position at the time of the sub-field drawing is out of the deflection distance range, the flow returns to steps S43 and S44. The window frame determination section 132 waits until the stage position at the time of the sub-field drawing is within a deflection distance range. Further, a drawing flag written in the memory 133a is read and stored in a register, not shown.

(f) In step S45, a distortion correction section 134 calculates a distance from the present stage position to a targeted sub-field drawing position. Then, the distortion correction section 134 reads a correction coefficient corresponding to the deflection distance from a correction coefficient memory 135 to calculate deflection distortion. Thereafter, the distortion correction section 134 determines a deflection voltage.

(g) In step S46, a STG position predicting section 136 predicts sub-field drawing time based on the number of shots in sub-field included in the sub-field position data (drawing data) and average shot time.

(h) In step S47, the STG position predicting section 136 acquires an elapsed time of the timer from starting to count in step S40. Then, the predicting section 136 adds a sub-field drawing time calculated in step S46 to an elapsed time after sub-field drawing ends. Thereafter, based on the predicted stage position data stored in a memory 133b, the predicting section 136 predicts a stage movement amount after drawing is carried out on the sub-field drawing currently being in computation. The predicted stage movement amount with regard to the elapsed time after sub-field drawing is obtained by interpolating the predicted stage position data 401c stored in the memory 133b. The obtained predicted stage movement amount is written in the memory 133a for using the next sub-field computing.

A flag for using the predicted stage movement amount at the next sub-field calculation is set to 1 and then written in the memory 133a. In order to calculate the predicted stage movement amount, the total time of data read time, window frame determination time and operating time is compared with the predicted sub-field drawing time. The total time or the predicted sub-field drawing time, whichever is larger, is multiplied by the stage speed to calculate the predicted stage movement amount. In this way, a high-accuracy predicted stage movement amount is obtained even if the number of shots in sub-field is less and the drawing time is extremely short.

(i) The process flow proceeds to the next step S50 if the drawing flag stored in step S44 in the register, not shown, is zero in step S48 in an output determination section 137.

(j) Conversely, if the drawing flag is 1 in step S48, the process flow proceeds to step S49. The output determination section 137 waits until a previous sub-field drawing end signal is detected. When the previous sub-field end signal is detected, the process flow proceeds to the step S50.

(k) In step S50, the transfer section 138 transfers data to the deflection amplifier 139.

(l) In step S51, the transfer section 138 waits until the predetermined settling time elapses.

(m) In step S52, when the voltage of the deflection amplifier 139 is stable, a drawing start (beam irradiation) signal is sent to the deflection amplifier 139.

(n) In step S53, if the data reading section 131 does not detect a stripe end flag showing the last sub-field in the stripe, the flow proceeds to step S54, and then, the drawing flag is set to 1, and the flow returns to step S51.

(o) Conversely, in step S53, if the data reading section 131 detects a stripe end flag showing the last sub-field in the stripe, the sub-field drawing end signal is detected, and then, the stripe drawing ends.

In electron beam drawing apparatus and method according to the second embodiment of the present invention, the stage position is predicted based on the elapsed time from the start of the stripe drawing. However, different methods may be used. For example, a stage position when each sub-field is drawn is predicted, and then, a predicted stage movement amount after each sub-field drawing end is stored in the memory 133b.

Further, according to the electron beam drawing apparatus and method according to the second embodiment, the deflection control circuit predicts the stage position of the sub-field position to be drawn. In this way, deflection distortion is computed without waiting the previous sub-field drawing end. Therefore, wasteful time is largely reduced, and productivity by electron beam drawing is greatly improved.

Therefore, according to the electron beam drawing apparatus and method of the above-mentioned embodiments, the deflection control circuit predicts the stage position of the sub-field position to be drawn. Thereby, deflection distortion is computed without waiting the previous sub-field drawing end. Therefore, wasteful time is largely reduced, and productivity by electron beam drawing is greatly improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam drawing apparatus of stage continuous-moving type comprising:
an acquisition unit which acquires a position data of an Nth drawing area;
an acquisition unit which acquires a stage position and a stage speed of a stage;
a prediction unit which predicts a stage position of the stage when drawing a pattern on the Nth drawing area is carried out;
a determination unit which determines whether or not a distance from the predicted stage position to the Nth drawing area position is less than a deflection distance;
a decision unit which, when the determination unit determines that the distance from the predicted stage position to the Nth drawing area position is less than the deflection distance, corrects a deflection distortion in accordance with the determined distance and decides a deflection voltage;
a detection unit which detects a drawing end of an (N-1)th drawing area when drawing a pattern on the (N-1)th drawing area is ended; and
a drawing unit which, when the drawing end of the (N-1)th drawing area is detected, deflects an electron beam in accordance with the deflection voltage decided by the decision unit to draw a pattern on the Nth drawing area.

2. An electron beam drawing apparatus according to claim 1, wherein the predicted stage position prediction unit includes:
a calculating section which calculates a stage movement amount of the stage at the drawing end of the (N-1)th drawing area based on a drawing time of (N-1)th drawing area and the stage position acquired by the acquisition unit; and
an acquisition section which acquires the predicted stage position of the stage when drawing a pattern on the Nth drawing area is carried out based on the calculated stage movement amount and the stage position acquired by the acquisition unit.

3. An electron beam drawing apparatus according to claim 1, wherein the predicted stage position prediction unit includes a determination section which determines the drawing time of the drawing area based on the number of shots on the drawing area and an average time of the shots.

4. An electron beam drawing apparatus according to claim 1, wherein the predicted stage position prediction unit includes an acquisition section which acquires the predicted stage position by using a table showing an elapsed time from a start of the drawing and a stage movement amount of the stage.

5. An electron beam drawing apparatus according to claim 4, wherein, when a pattern arrangement in the drawing area is constant, the stage movement amount to the elapsed time is constant.

6. An electron beam drawing apparatus according to claim 4, wherein, when a pattern arrangement in the drawing area is coarse or dense, the stage movement amount to the elapsed time varies in accordance with the coarse or dense of the pattern arrangement in the drawing area.

7. An electron beam drawing apparatus according to claim 1, further comprising a storage unit which stores at least position data of the drawing area.

8. An electron beam drawing method of stage continuous-moving type comprising:
acquiring a position data of an Nth drawing area;
acquiring a stage position and a stage speed of a stage;
predicting a stage position of the stage when drawing a pattern on the Nth drawing area is carried out;
determining whether or not a distance from the predicted stage position to the Nth drawing area position is less than a deflection distance;
correcting a deflection distortion in accordance with the determined distance and decides a deflection voltage, when the determination unit determines that the distance from the predicted stage position to the Nth drawing area position is less than the deflection distance;
detecting a drawing end of an (N-1)th drawing area when drawing a pattern on the (N-1)th drawing area is ended; and
deflecting an electron beam in accordance with the deflection voltage decided by the decision unit and drawing a pattern on the Nth drawing area, when the drawing end of the (N-1)th drawing area is detected.

9. An electron beam drawing method according to claim 8, wherein predicting the stage position includes:
calculating a stage movement amount of the stage at the drawing end of the (N-1)th drawing area based on a drawing time of (N-1)th drawing area and the stage position acquired by the acquisition unit; and
acquiring the predicted stage position of the stage when drawing a pattern on the Nth drawing area is carried out based on the calculated stage movement amount and the stage position acquired by the acquisition unit.

10. An electron beam drawing method according to claim 8, wherein predicting the stage position includes determining the drawing time of the drawing area based on the number of shots on the drawing area and an average time of the shots.

11. An electron beam drawing method according to claim 8, wherein predicting the stage position includes acquiring the predicted stage position by using a table showing an elapsed time from a start of the drawing and a stage movement amount of the stage.

12. An electron beam drawing method according to claim 11, wherein, when a pattern arrangement in the drawing area is constant, the stage movement amount to the elapsed time is constant.

13. An electron beam drawing method according to claim 11, wherein, when a pattern arrangement in the drawing area is coarse or dense, the stage movement amount to the elapsed time varies in accordance with the coarse or dense of the pattern arrangement in the drawing area.

14. An electron beam drawing method according to claim 8, which is applied to an electron beam drawing apparatus of stage continuous-moving type comprising:
an acquisition unit which acquires a position data of an Nth drawing area;
an acquisition unit which acquires a stage position and a stage speed of a stage;
a prediction unit which predicts a stage position of the stage when drawing a pattern on the Nth drawing area is carried out;
a determination unit which determines whether or not a distance from the predicted stage position to the Nth drawing area position is less than a deflection distance;
a decision unit which, when the determination unit determines that the distance from the predicted stage position to the Nth drawing area position is less than the deflection distance, corrects a deflection distortion in accordance with the determined distance and decides a deflection voltage;
a detection unit which detects a drawing end of an (N-1)th drawing area when drawing a pattern on the (N-1)th drawing area is ended; and
a drawing unit which, when the drawing end of the (N-1)th drawing area is detected, deflects an electron beam in accordance with the deflection voltage decided by the decision unit and drawing a pattern on the Nth drawing area.

15. A semiconductor device manufacturing method comprising:
acquiring a position data of an Nth drawing area on an semiconductor wafer to be processed;
acquiring a stage position and a stage speed of a stage on which the semiconductor wafer is placed;
predicting a stage position of the stage when drawing a pattern on the Nth drawing area is carried out;
determining whether or not a distance from the predicted stage position to the Nth drawing area position is less than a deflection distance;
correcting a deflection distortion in accordance with the determined distance and decides a deflection voltage, when the determination unit determines that the distance from the predicted stage position to the Nth drawing area position is less than the deflection distance;
detecting a drawing end of an (N-1)th drawing area on the semiconductor wafer when drawing a pattern on the (N-1)th drawing area is ended; and
deflecting an electron beam in accordance with the deflection voltage decided by the decision unit to draw a pattern on the Nth drawing area of the semiconductor wafer, when the drawing end of the (N-1)th drawing area of the semiconductor wafer is detected.

16. A semiconductor device manufacturing method according to claim 15, wherein predicting the stage position includes:
calculating a stage movement amount of the stage at the drawing end of the (N-1)th drawing area based on a drawing time of (N-1)th drawing area and the stage position acquired by the acquisition unit; and
acquiring the predicted stage position of the stage when drawing a pattern on the Nth drawing area is carried out based on the calculated stage movement amount and the stage position acquired by the acquisition unit.

17. A semiconductor device manufacturing method according to claim 15, wherein predicting the stage position includes determining the drawing time of the drawing area based on the number of shots on the drawing area and an average time of the shots.

18. A semiconductor device manufacturing method according to claim 15, wherein predicting the stage position includes acquiring the predicted stage position by using a table showing an elapsed time from a start of the drawing and a stage movement amount of the stage.

19. A semiconductor device manufacturing method according to claim 18, wherein, when a pattern arrangement in the drawing area is constant, the stage movement amount to the elapsed time is constant.

20. A semiconductor device manufacturing method according to claim 18, wherein, when a pattern arrangement in the drawing area is coarse or dense, the stage movement amount to the elapsed time varies in accordance with the coarse or dense of the pattern arrangement in the drawing area.
